(19) United States
(12) Patent Application Publication
(10) Pub. No.: US 2025/0285702 A1
(43) Pub. Date: Sep. 11, 2025

(54) MEMORY SYSTEM AND METHOD OF CONTROLLING NON-VOLATILE MEMORY

(71) Applicant: Kioxia Corporation, Tokyo (JP)

(72) Inventors: Takahiro KUBOTA, Kawasaki Kanagawa (JP); Yuta KUMANO, Kawasaki Kanagawa (JP); Daiki WATANABE, Kawasaki Kanagawa (JP); Hironori UCHIKAWA, Fujisawa Kanagawa (JP)

(73) Assignee: Kioxia Corporation, Tokyo (JP)

(21) Appl. No.: 18/829,445

(22) Filed: Sep. 10, 2024

(30) Foreign Application Priority Data
Mar. 8, 2024 (JP) 2024-035460

(51) Int. Cl. G11C 29/42

(52) U.S. Cl. CPC G11C 29/42

(57) ABSTRACT

A memory system according to the present disclosure includes a non-volatile memory that stores a concatenated code of a first error-correcting code and a second error-correcting code, and a memory controller. When a first decoding processing using the first error-correcting code for read information read from the non-volatile memory or a checking processing of checking that the read information does not include an error succeeds, the memory controller generates a first parity bit that is a parity bit of the second error-correcting code, and calculates a first evaluation value for determining whether the read information includes the error by using the generated first parity bit and a second parity bit that is a parity bit of the second error-correcting code after second decoding processing is executed. The memory controller determines whether the read information includes the error by using the first evaluation value.

### CROSS-REFERENCE TO RELATED APPLICATIONS

This application is based upon and claims the benefit of priority from Japanese Patent Application No. 2024-035460, filed on Mar. 8, 2024; the entire contents of which are incorporated herein by reference.

### FIELD

Embodiments described herein relate generally to a memory system and a method.

### BACKGROUND

In a memory system, in order to protect data stored in a memory such as a NAND flash memory, data subjected to error correction encoding is stored in the memory. Therefore, when the data stored in the memory is read, the data subjected to error correction encoding (also referred to as a received word) read from the memory is decoded to restore the data before the error correction encoding.

### BRIEF DESCRIPTION OF THE DRAWINGS

FIG. 1 is a block diagram of a memory system according to a first embodiment;

FIG. 2 is a diagram for explaining an example of an outer code and an inner code;

FIG. 3 is a block diagram of a decoder according to the first embodiment;

FIG. 4 is a flowchart of decoding processing according to the first embodiment;

FIG. 5 is a flowchart of determination processing according to the first embodiment;

FIG. 6 is a diagram illustrating an example in which decoding processing using an outer code succeeds;

FIG. 7 is a diagram illustrating an example in which decoding processing using an outer code fails;

FIG. 8 is a diagram for explaining an example of determining as false positive;

FIG. 9 is a diagram for explaining an example of determination processing using an evaluation value;

FIG. 10 is a diagram for explaining an example of determination processing using an evaluation value;

FIG. 11 is a block diagram of a decoder according to a second embodiment;

FIG. 12 is a flowchart of determination processing according to the second embodiment;

FIG. 13 is a diagram for explaining an example of determination processing using an evaluation value;

FIG. 14 is a block diagram of a decoder according to a third embodiment;

FIG. 15 is a flowchart of checking processing according to the third embodiment; and

FIG. 16 is a diagram for explaining an example of checking processing according to the third embodiment.

### DETAILED DESCRIPTION

In general, according to one embodiment, a memory system includes a non-volatile memory configured to store a concatenated code of a first error-correcting code and a second error-correcting code, and a memory controller. When a first decoding processing using the first error-correcting code for read information read from the non-volatile memory or a checking processing of checking that the read information does not include an error succeeds, the memory controller generates a first parity bit that is a parity bit of the second error-correcting code, and calculates a first evaluation value for determining whether the read information includes the error by using the generated first parity bit and a second parity bit that is a parity bit of the second error-correcting code after second decoding processing is executed. The memory controller determines whether the read information includes the error by using the first evaluation value.

Exemplary embodiments of a memory system and a method will be explained below in detail with reference to the accompanying drawings. The present invention is not limited by the following embodiments.

### First Embodiment

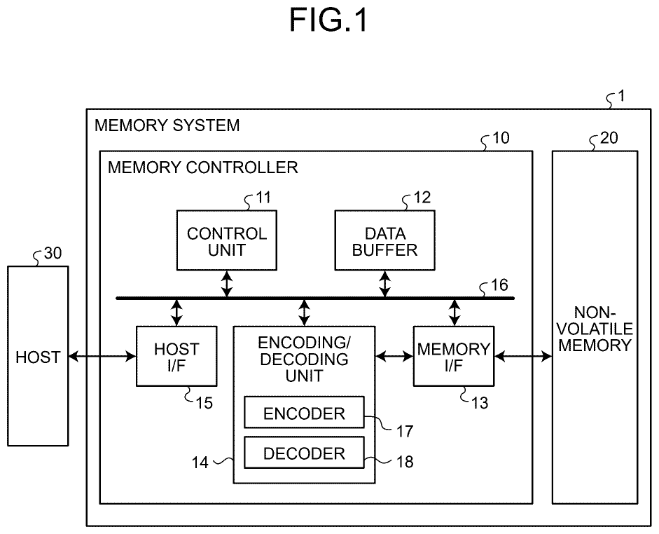

FIG. 1 is a block diagram illustrating a schematic configuration example of a memory system according to a first embodiment. As illustrated in FIG. 1, a memory system 1 includes a memory controller 10 and a non-volatile memory 20. The memory system 1 can be connected to a host 30, and FIG. 1 illustrates a state in which the memory system 1 is connected to the host 30. The host 30 may be, for example, an electronic device such as a personal computer or a mobile terminal.

The non-volatile memory 20 is a non-volatile memory that stores data in a non-volatile manner, and is, for example, a NAND memory. In the following description, a case where a NAND memory is used as the non-volatile memory 20 will be exemplified, but a storage device other than the NAND memory, such as a three-dimensional structure flash memory, a resistance random access memory (ReRAM), or a ferroelectric random access memory (FeRAM), can be used as the non-volatile memory 20. Further, the non-volatile memory 20 is not necessarily a semiconductor memory, and the present embodiment can also be applied to various storage media other than the semiconductor memory.

The memory system 1 may be a memory card or the like in which the memory controller 10 and the non-volatile memory 20 are configured as one package, or may be a solid state drive (SSD) or the like.

The memory controller 10 controls writing to the non-volatile memory 20 in accordance with a write request from the host 30. In addition, the memory controller 10 controls reading from the non-volatile memory 20 in accordance with a read request from the host 30. The memory controller 10 includes a host interface (host I/F) 15, a memory interface (memory I/F) 13, a control unit 11, an encoding/decoding unit (codec) 14, and a data buffer 12. The host I/F 15, the memory I/F 13, the control unit 11, the encoding/decoding unit 14, and the data buffer 12 are mutually connected by an internal bus 16. Part or all of the operation of each component of the memory controller 10 may be realized by executing firmware by a central processing unit (CPU) or may be realized by hardware.

The host I/F 15 performs processing according to an interface standard with the host 30, and outputs a command received from the host 30, user data to be written, and the like to the internal bus 16. In addition, the host I/F 15 transmits user data read from the non-volatile memory 20 and restored, a response from the control unit 11, and the like to the host 30.

The memory I/F 13 performs write processing to the non-volatile memory 20 based on an instruction from the control unit 11. In addition, the memory I/F 13 performs read processing from the non-volatile memory 20 based on an instruction from the control unit 11.

The control unit 11 integrally controls each component of the memory system 1. When receiving a command from the host 30 via the host I/F 15, the control unit 11 performs control in accordance with the command. For example, the control unit 11 instructs the memory I/F 13 to write the user data and the parity bit to the non-volatile memory 20 in accordance with a command from the host 30. In addition, the control unit 11 instructs the memory I/F 13 to read the user data and the parity bit from the non-volatile memory 20 in accordance with a command from the host 30.

When receiving a write request of the user data from the host 30, the control unit 11 accumulates the user data in the data buffer 12, and determines a storage area (memory area) of the user data in the non-volatile memory 20. That is, the control unit 11 manages a write destination of the user data. The correspondence between the logical address of the user data received from the host 30 and the physical address indicating the storage area on the non-volatile memory 20 in which the user data is stored is stored as an address conversion table.

In addition, when receiving a read request from the host 30, the control unit 11 converts a logical address designated by the read request into a physical address using the above-described address conversion table, and instructs the memory I/F 13 to perform reading from the physical address.

In the NAND memory, writing and reading are generally performed in units of data called pages, and erasing is performed in units of data called blocks. In the present embodiment, a plurality of memory cells connected to the same word line is referred to as a memory cell group. When the memory cell is a single-level cell (SLC), one memory cell group corresponds to one page. When the memory cell is a multi-level cell (MLC), one memory cell group corresponds to a plurality of pages. Further, each memory cell is connected to a word line and is also connected to a bit line. Therefore, each memory cell can be identified by an address for identifying a word line and an address for identifying a bit line.

The data buffer 12 temporarily stores the user data received from the host 30 by the memory controller 10 until the user data is stored in the non-volatile memory 20. In addition, the data buffer 12 temporarily stores the user data read from the non-volatile memory 20 until the user data is transmitted to the host 30. As the data buffer 12, for example, a general-purpose memory such as a static random access memory (SRAM) or a dynamic random access memory (DRAM) can be used.

The user data transmitted from the host 30 is transferred to the internal bus 16 and temporarily stored in the data buffer 12. The encoding/decoding unit 14 encodes the user data to generate a code word. Further, the encoding/decoding unit 14 decodes a received word that is data read from the non-volatile memory 20 to restore the user data. Therefore, the encoding/decoding unit 14 includes an encoder 17 and a decoder 18. Note that the data encoded by the encoding/decoding unit 14 may include control data or the like used inside the memory controller 10 in addition to the user data.

Next, the write processing of the present embodiment will be described. The control unit 11 instructs the encoder 17 to encode the user data during writing the user data to the non-volatile memory 20. At that time, the control unit 11 determines a storage location (storage address) of the code word in the non-volatile memory 20, and also instructs the memory I/F 13 on the determined storage location.

The encoder 17 encodes the user data on the data buffer 12 in accordance with an instruction from the control unit 11 to generate a code word. As the encoding method, for example, an encoding method using an algebraic code such as a Bose-Chaudhuri-Hocquenghem (BCH) code and a Reed-Solomon (RS) code, and an encoding method (product code or the like) using these codes as component codes in the row direction and the column direction can be adopted. The memory I/F 13 performs control to store a code word in a storage location on the non-volatile memory 20 instructed from the control unit 11.

Next, processing during reading from the non-volatile memory 20 of the present embodiment will be described. During reading from the non-volatile memory 20, the control unit 11 designates an address on the non-volatile memory 20 and instructs the memory I/F 13 to perform reading. Furthermore, the control unit 11 instructs the decoder 18 to start decoding. The memory I/F 13 reads data from the designated address of the non-volatile memory 20 according to an instruction of the control unit 11, and inputs the read data to the decoder 18 as a received word. The decoder 18 decodes the received word that is data read from the non-volatile memory 20.

Next, an error-correcting code (code word) used in the present embodiment will be described. In the present embodiment, the encoder 17 generates a concatenated code as an error-correcting code. The concatenated code is, for example, a code based on an error-correcting code C1 (first error-correcting code) generated using data (user data) stored in the non-volatile memory 20 and an error-correcting code C2 (second error-correcting code) generated using the error-correcting code C1. Hereinafter, the error-correcting code C1 is referred to as an outer code, and the error-correcting code C2 is referred to as an inner code.

The outer code is used to remove a residual error in a case where the correction cannot be performed by the error correction using the inner code. The outer code can be, for example, a BCH code capable of 4-bit correction. In decoding using the outer code (residual error removal), there is a possibility of occurrence of erroneous correction, and thus determination processing of determining whether or not erroneous correction has not occurred may be executed. The inner code can be, for example, a multi-dimensional error-correcting code.

Here, the multi-dimensional error-correcting code refers to the one in which symbols that are at least one constituent unit of the error-correcting code are protected in a multiple manner by a plurality of smaller component codes. Furthermore, one symbol includes, for example, one bit (element of a binary field) or an element of an alphabet such as a finite field other than a binary field. In order to facilitate the description, a binary error-correcting code in which one symbol includes one bit will be described below as an example. In the description, there may be a part where symbols and bits are mixed, but both represent the same meaning.

An example of the multi-dimensional error-correcting code is a product code. The product code has a structure in which each information symbol that is a constituent unit of the user data is protected by a Hamming code including a parity symbol of a predetermined parity length in each of the row direction and the column direction. That is, in the product code, all symbols are doubly protected by component codes in the row direction (referred to as dimension 1) and the column direction (referred to as dimension 2). Note that the multi-dimensional error-correcting code is not limited thereto, and may be, for example, a generalized low density parity check code (generalized LDPC code) or the like. In a general multi-dimensional error-correcting code including a generalized LDPC code, the multiplicity of protection may be different for each symbol, and the component codes cannot be grouped as in dimension 1 and dimension 2, but the present technology can also be applied to such a code configuration.

Hereinafter, for simplicity, an example of using a two-dimensional error-correcting code (product code) in which each symbol is protected by two component codes that can be grouped into dimension 1 and dimension 2 will be described. Each component code of each dimension includes one or more component codes determined for each dimension. Hereinafter, a component code corresponding to each dimension including one or more component codes may be referred to as a component code group. For example, the component code group of the dimension 1 includes n1 component codes, and the component code group of the dimension 2 includes n2 component codes. The applicable error-correcting code is not limited thereto, and may be an N-dimensional error-correcting code in which at least one symbol among symbols forming the code is protected by N component code groups (N is an integer of 2 or more). When expressed by the number of component codes included in each component code group, the N-dimensional error-correcting code is protected by M component codes (M is a sum of ni (1≤i≤N), N is an integer of 2 or more, and ni is the number of i-th dimensional component codes).

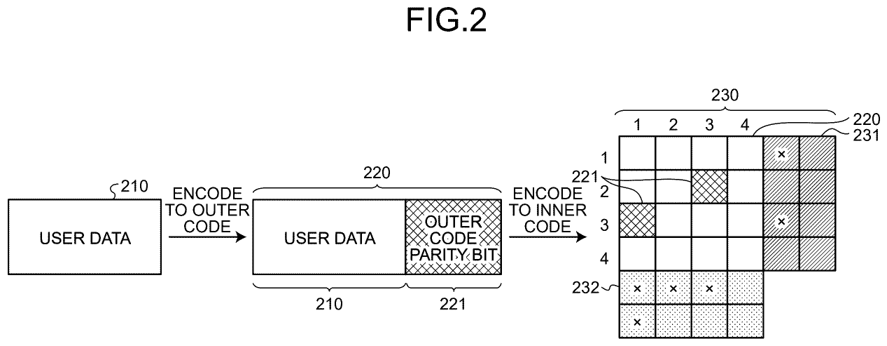

An example of the outer code and the inner code will be described with reference to FIG. 2. In FIG. 2 and the subsequent drawings, examples in which a product code obtained by encoding information bits of four bits in the column direction (columns 1 to 4) and information bits of four bits in the row direction (rows 1 to 4) is used as an inner code will be described.

As illustrated in FIG. 2, the encoder 17 first encodes user data 210 to an outer code 220. The outer code 220 includes the user data 210 and an outer code parity bit 221. Next, the encoder 17 encodes the outer code 220 into inner code 230. The inner code 230 includes the outer code 220, a parity bit 231 in the row direction of the inner code, and a parity bit 232 in the column direction of the inner code.

The inner code is, for example, a product code having a BCH code capable of correcting three-bit as a component code. In the example of FIG. 2, four component codes in the row direction (dimension 1) and four component codes in the column direction (dimension 2) are BCH codes that can correct three bits.

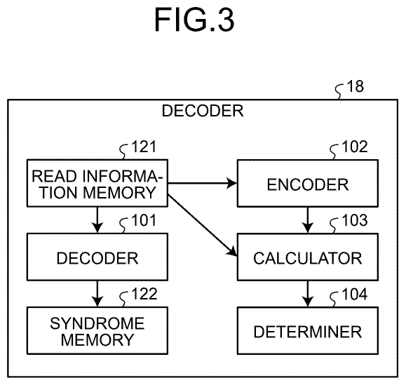

Next, a configuration example of the decoder 18 that decodes such a concatenated code will be described. FIG. 3 is a block diagram illustrating a schematic configuration example of the decoder 18 of the first embodiment. As illustrated in FIG. 3, the decoder 18 includes a read information memory 121, a syndrome memory 122, a decoder 101, an encoder 102, a calculator 103, and a determiner 104.

The read information memory 121 is realized by, for example, an SRAM. The syndrome memory 122 is realized by, for example, a register. The decoder 101, the encoder 102, the calculator 103, and the determiner 104 are realized by at least one of a register, an adder, a multiplier, and other arithmetic units. The register is realized by, for example, a logic circuit such as a flip-flop. The adder, the multiplier, the selector, and the other arithmetic units are realized by, for example, a logic circuit.

The read information memory 121 is a memory that stores read information which is data read from the non-volatile memory 20.

The syndrome memory 122 is a memory that stores syndromes of error-correcting codes. The syndrome is information that can be used to determine whether or not there is an error in the read information. For example, when the values of all syndromes are 0, it is determined that there is no error in the read information. The syndrome memory 122 stores a syndrome SD1 of the outer code calculated by decoding processing DEC1 (first decoding processing) using the outer code and a plurality of syndromes SD2 for a plurality of component codes calculated by decoding processing DEC2 (second decoding processing) using the inner code.

The decoder 101 executes the decoding processing DEC1 using the outer code and the decoding processing DEC2 using the inner code. For example, the decoder 101 first executes the decoding processing DEC2 using the inner code on the read information. When the decoding by the decoding processing DEC2 fails, the decoder 101 executes the decoding processing DEC1 using the outer code on the read information. The decoder 101 stores the read information after each decoding processing is executed in the read information memory 121.

The encoder 102 performs encoding of an inner code on the information bits among the inner codes stored in the read information memory 121, and regenerates a parity bit P1 (first parity bit) of the inner code. For example, the encoder 102 regenerates the parity bit P1 for each of the plurality of component codes forming the product code that is an inner code. Note that the function of the encoder 102 may be provided in the encoder 17.

In the example of FIG. 2, the encoder 102 re-encodes the 4-bit information bits in the row direction, and regenerates the parity bit 231 in the row direction. In addition, the encoder 102 re-encodes the 4-bit information bits in the column direction, and regenerates the parity bit 232 in the column direction.

The parity bit P1 to be regenerated is used to calculate an evaluation value used in the determination processing. The determination processing is a process of determining whether or not an error is included in the read information. The determination processing corresponds to a process of determining whether or not a result indicating that the decoding processing DEC1 using the outer code or the checking processing using the outer code has succeeded is correct in a case where these processing have succeeded. Therefore, the parity bit P1 is regenerated by the encoder 102 when the decoding processing DEC1 succeeds or when the checking processing succeeds.

The checking processing is, for example, a process of checking that the read information does not include an error (that there is no residual error) using an outer code. For example, the checking processing is executed to check whether or not an error remains in the user data portion using the syndrome SD1 of the outer code or the like every time each component code of the inner code is decoded. Even in the middle of the decoding processing DEC2, if it is checked that no error remains in the user data portion by the checking processing, the decoding process DEC2 can be ended as a decoding success.

The checking processing may be any processing, and is executed by, for example, the following procedure. In a case where the syndrome SD1 of the outer code is satisfied and the syndrome SD2 of the component codes of the inner codes whose number is equal to or larger than the threshold is satisfied, a check result indicating that no error is included in the read information is output.

The calculator 103 calculates an evaluation value E1 (first evaluation value) used in the determination processing. For example, the calculator 103 calculates the evaluation value E1 using the regenerated parity bit P1 and a parity bit P2 (second parity bit) of the inner code after the decoding processing DEC2 using the inner code is executed. The parity bit P2 of the inner code after the decoding processing DEC2 is executed corresponds to a portion of the parity bit (the parity bit 231 in the row direction and the parity bit 232 in the column direction) among the inner codes stored in the read information memory 121. Details of a method of calculating the evaluation value E1 by the calculator 103 will be described later.

The determiner 104 executes determination processing using the calculated evaluation value E1. For example, when the evaluation value E1 is equal to or less than a threshold TH_A, the determiner 104 determines that no error is included in the read information (decoding success). In the case of the determination processing after the decoding processing DEC1 using the outer code has succeeded, the fact that the evaluation value E1 is equal to or less than the threshold TH_A corresponds to the determination that there is no erroneous correction in the decoding processing DEC1. In the case of determination processing after the checking processing, the fact that the evaluation value E1 is equal to or less than the threshold TH_A corresponds to the determination that the checking processing has been normally completed.

The determiner 104 outputs a result of the

determination processing as a decoding result. For example, in a case where it is determined that no error is included in the read information by the determination processing, the determiner 104 outputs a decoding success. In a case where it is determined that an error is included in the read information by the determination processing, the determiner 104 outputs a decoding failure. Note that it can be interpreted that processing including not only the processing by the determiner 104 but also the regeneration of the parity bit P1 (first parity bit) by the encoder 102 and the calculation of the evaluation value E1 by the calculator 103 corresponds to the determination processing.

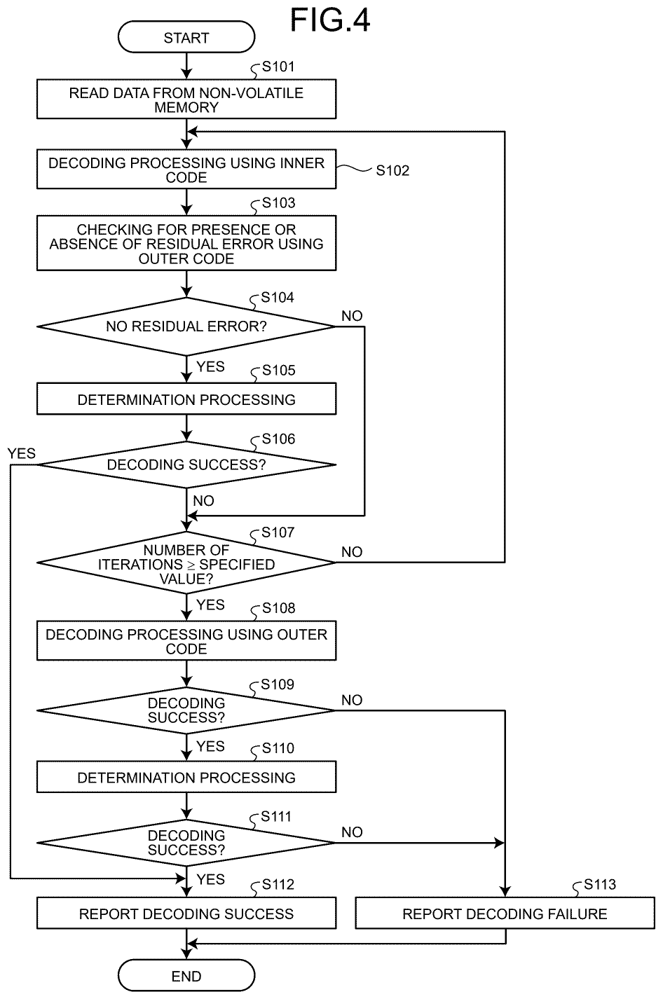

Next, the procedure of decoding processing by the memory system 1 of the present embodiment will be described. FIG. 4 is a flowchart illustrating an example of decoding processing according to the present embodiment.

The control unit 11 reads the error-correcting code from non-volatile memory 20, and obtains read information (step S101). The control unit 11 transfers the read information that is read out to the read information memory 121 and store it therein.

Next, the decoder 18 executes the decoding processing DEC2 using the inner code (step S102). In a case where the product code as illustrated in FIG. 2 is used as the inner code, the decoder 18 repeats, for example, decoding of the component code in the row direction (dimension 1) and decoding of the component code in the column direction (dimension 2), thereby executing the decoding processing DEC2. In this case, step S102 in FIG. 4 corresponds to decoding of the component code for one dimension (dimension 1 or dimension 2).

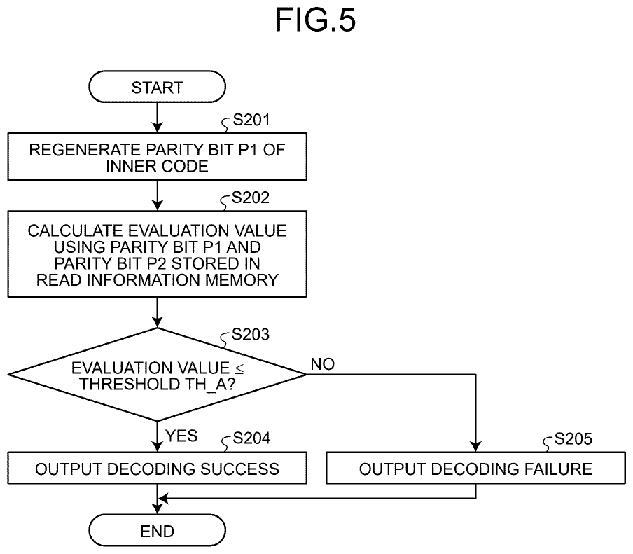

When the decoding of the component code of one dimension is completed, the decoder 18 executes checking processing for the presence or absence of a residual error using the outer code (step S103). The decoder 18 determines whether or not there is no residual error in the result of the checking processing (check result) (step S104). When the check result indicates that there is no residual error (step S104: Yes), the decoder 18 executes determination processing (step S105). The procedure of the determination processing will be described with reference to FIG. 5.

After the determination processing, the decoder 18 determines whether or not the result of the determination processing is a decoding success (step S106). If it is a decoding success (step S106: Yes), the decoder 18 reports the decoding word together with the decoding success (step S112) to an external control unit or the like, and ends the decoding processing.

If the result of the determination processing is a decoding failure (step S106: No) and if it is determined in step S104 that the check result does not indicate no residual error (there is a residual error) (step S104: No), the decoder 18 determines whether or not the number of iterations has reached a preset specified value (step S107). When the number of iterations has not reached the specified value (step S107: No), the decoder 18 increases the number of iterations by 1, and returns to step S102 to repeat the processing. The number of iterations is, for example, the number of repetitions of the operations of steps S102 to S106.

In a case where the number of iterations has reached the specified value (step S107: Yes), the decoder 18 executes the decoding processing DEC1 using the outer code (step S108). The decoder 18 determines whether or not the decoding by the decoding processing DEC1 succeeds (step S109).

If it is determined that the decoding by the decoding processing DEC1 has succeeded (step S109: Yes), the decoder 18 executes the determination processing (step S110). The procedure of the determination processing will be described with reference to FIG. 5.

After the determination processing, the decoder 18 determines whether or not the result of the determination processing is a decoding success (step S111). If it is a decoding success (step S111: Yes), the decoder 18 reports the decoding word together with the decoding success to an external control unit or the like (step S112), and ends the decoding processing.

In a case where it is determined in step S111 or step S109 that the decoding has failed (step S111: No, step S109: No), the decoder 18 reports the decoding failure to an external control unit or the like (step S113), and ends the decoding processing.

Next, the procedure of determination processing in steps S105 and S110 will be described. FIG. 5 is a flowchart illustrating an example of determination processing according to the present embodiment.

The encoder 102 regenerates the parity bit P1 of the inner code (step S201). The calculator 103 calculates the evaluation value E1 using the regenerated parity bit P1 and the parity bit P2 of the inner code generated in the decoding processing DEC2 using the inner code and stored in the read information memory 121, for example (step S202).

The determiner 104 determines whether or not the evaluation value E1 is equal to or less than the threshold TH_A (step S203). When the evaluation value E1 is equal to or smaller than the threshold TH_A (step S203: Yes), the determiner 104 outputs the decoding success as a determination result (step S204). When the evaluation value E1 is larger than the threshold TH_A (step S203: No), the determiner 104 outputs the decoding failure as a determination result (step S205).

Next, details of a method of calculating the evaluation value E1 by the calculator 103 will be described. The calculator 103 can calculate the evaluation value E1 by, for example, the following calculation methods M1 to M3.

(M1) A Hamming distance between the parity bit P1 and the parity bit P2 is calculated for each of the plurality of component codes. A sum of a plurality of Hamming distances for a plurality of component codes is calculated as the evaluation value E1.

(M2) A Hamming distance between the parity bit P1 and the parity bit P2 is calculated for each of the plurality of component codes. The number of component codes whose Hamming distance is larger than a threshold TH_B (first threshold) (excess number count) is calculated as the evaluation value E1.

(M3) A Hamming distance between the parity bit P1 and the parity bit P2 is calculated for each of the plurality of component codes. The sum of a predetermined number (L, L is an integer of 1 or more) of Hamming distances in descending order is calculated as the evaluation value E1.

In addition, here, what calculated by the exclusive OR (EXOR) of the parity bit P1 and the parity bit P2 is referred to as a parity error vector, and the Hamming distance is referred to as a weight of the parity error vector.

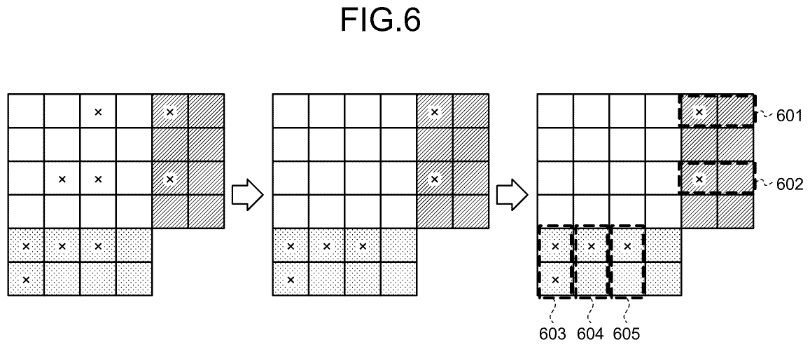

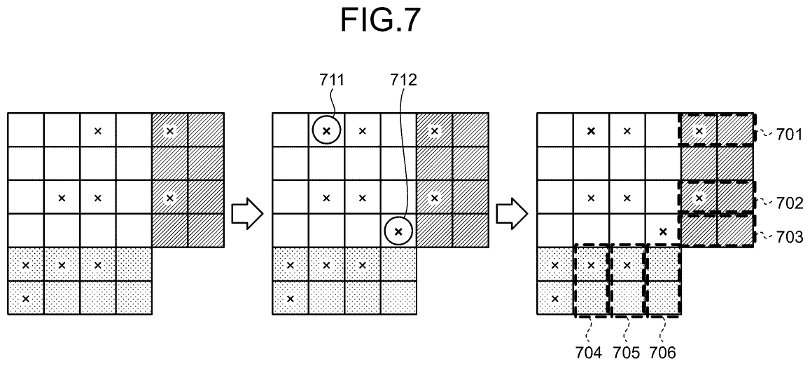

Next, an example of determination processing using the evaluation value E1 calculated by the above calculation method will be described. FIGS. 6 and 7 are diagrams for explaining an example of determination processing using the evaluation value E1 calculated by the calculation method M1. FIG. 6 illustrates an example of a case where decoding by the decoding processing DEC1 succeeds (inerrable correction).

The left part of FIG. 6 illustrates a state in which an error remains in the user data portion (double protection portion) after the decoding processing DEC2 using the inner code. Note that “×” indicates a portion where an error remains. The central part of FIG. 6 illustrates a state after the decoding processing DEC1 using the outer code is executed for residual error removal. In the example of FIG. 6, all the residual errors in the double protection portion are removed by the residual error removal (inerrable correction).

The right part of FIG. 6 illustrates a state in which the evaluation value E1 is calculated using the user data from which the residual error has been removed, and it is determined whether or not there is an erroneous correction in the decoding processing DEC1. During inerrable correction, the parity bit P2 of the inner code after execution of the decoding processing DEC2 includes parity bits 601 to 605 including a channel-induced error or an error induced by erroneous correction of component code decoding. Note that the channel-induced error represents an error included in the user data before decoding. On the other hand, since the residual errors have been removed, the regenerated parity bit P1 is a correct parity bit not including an error. The Hamming distance of the component code including the channel-induced error is about less than 1 bit on average. Since the evaluation value E1 in the case of the calculation method M1 is the sum of a plurality of Hamming distances for a plurality of component codes, for example, when the maximum number of erroneous corrections is 3, the evaluation value E1 can be suppressed to about the number of component codes including residual errors ×4 bits (4 bits are a sum of 1 bit due to the channel and the maximum number of erroneous corrections of 3.).

FIG. 7 illustrates an example of a case where decoding by the decoding processing DEC1 fails (erroneous correction). In this case, as illustrated in the central part of FIG. 7, new errors 711 and 712 are added due to erroneous correction.

The right part of FIG. 7 illustrates a state in which the evaluation value E1 is calculated using the user data to which the errors have been added, and it is determined whether or not there is an erroneous correction in the decoding processing DEC1. Since the parity bit of the inner code is not corrected in the decoding processing DEC1, even during erroneous correction, the parity bit P2 of the inner code after the decoding processing DEC2 is executed is similar to that in FIG. 6, and becomes a parity bit including a channel-induced error. On the other hand, since an error remains due to erroneous correction, the regenerated parity bit P1 includes incorrect parity bits 701 to 706. The incorrect parity bits 501 to 506 shall be a random sequence. Since the sequence is random, half of the bits are different from the correct parity bit on average.

Assuming that the parity length of the component code is, for example, 32 bits, the Hamming distance of the component code including the residual errors is about 16 bits on average. The evaluation value E1 in the case of the calculation method M1 is a value about the sum of the number of channel-induced errors ×1 bit and the number of component codes including residual errors ×16 bits.

As illustrated in FIGS. 6 and 7, during erroneous correction (FIG. 7), since there is a contribution of the Hamming distance of the component code including the residual error, the evaluation value E1 takes a large value. Therefore, the determiner 104 determines that there is no erroneous correction (decoding success) when the evaluation value E1 is equal to or smaller than the threshold TH_A, and determines that there is erroneous correction (decoding failure) when the evaluation value E1 is larger than the threshold TH_A.

As described above, in the present embodiment, it is possible to determine whether or not erroneous correction has occurred in decoding by the decoding processing DEC1 on the basis of the evaluation value using the parity bit P1 of the regenerated inner code. As a result, error correction (decoding) can be executed with higher accuracy.

In the calculation method M1, when the Hamming distance (contribution value for each component code to the evaluation value E1) for each component code is calculated, whether or not the component code is a component code including a bit that has been erroneously corrected is not considered. Therefore, for example, in a case where the component code number is large, there is a possibility that the contribution value not induced by the erroneous correction, that is, the contribution value corresponding to the number of component codes including the channel-induced error or the error induced by the erroneous correction of the component code decoding is accumulated and exceeds the threshold TH_A. As a result, even in a case where the residual error removal has been normally completed (inerrable correction) by the decoding processing DEC1, there is a possibility that it is erroneously determined as erroneous correction. Note that the fact that there is no error but it is not correctly determined that “there is no error” by the determination processing is also referred to as false positive determination.

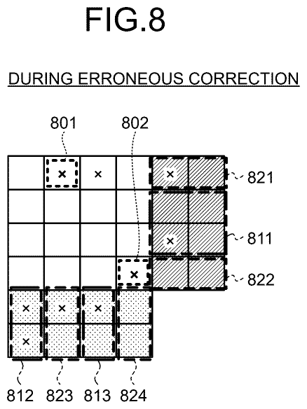

FIG. 8 is a diagram for explaining an example of determining as false positive. As illustrated in the central part of FIG. 8, an example in which new errors 801 and 802 are added due to erroneous correction will be described. Parity bits 811 to 813 corresponds to a parity bit of a component code that provides a contribution value not induced by erroneous correction. In FIG. 8, the component code number is 8 (row direction 4, column direction 4), and the number of component codes that provide contribution values not induced by erroneous correction is 4.

In a case where the component code number is large, the number of component codes that provide contribution values not induced by erroneous correction can be larger, for example, 80 to 500. Therefore, for example, even if the Hamming distance of the component code including the channel-induced error is less than about 1 bit on average, the sum of the contribution values not induced by the erroneous correction can be about 80 to 500, for example.

As described above, when the parity length of the component code is 32 bits, the contribution value for each component code induced by the erroneous correction is about 16 bits on average. In a case where the outer code is a BCH code capable of 4-bit correction, the number of component codes in which a contribution value induced by erroneous correction occurs is about 18 as described later. Therefore, the sum of the contribution values not induced by the erroneous correction is, for example, about 288 (=16×18).

As described above, in a case where the component code number is large, the sum of contribution values not induced by erroneous correction becomes relatively large, and a situation in which the sum exceeds the threshold TH_A for determining erroneous correction may occur. That is, even in the case of (correct correction), there may be a situation in which it is erroneously determined that it is an erroneous correction (false positive determination).

Here, the reason why the number of component codes in which a contribution value induced by erroneous correction occurs is about 18 will be described. In a case where the outer code is a BCH code capable of 4-bit correction, the Hamming distance between the two code words (bit strings that can be correct) is 4+1+4=9. Therefore, during erroneous correction, errors of at least 9 bits remain. Assuming that 9 bits of errors remain in each of the row direction and the column direction, a contribution value induced by erroneous correction occurs in 9×2=18 component codes.

The calculation methods M2 and M3 can be used to suppress the false positive determination as illustrated in FIG. 8. First, the calculation method M2 will be described. The calculation method M2 is a method of considering whether the component code is a component code including a bit that has been erroneously corrected, that is, a method of calculating the evaluation value E1 only from a contribution value estimated to be induced by erroneous correction.

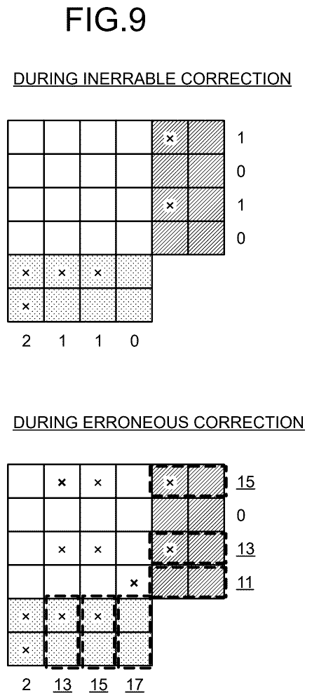

FIG. 9 is a diagram for explaining an example of determination processing using the evaluation value E1 calculated by the calculation method M2.

In the calculation method M2, the number of component codes whose Hamming distance is larger than the threshold TH_B (excess number count) is calculated as the evaluation value E1. A component code whose the Hamming distance is larger than the threshold TH_B corresponds to a component code in which a contribution value induced by erroneous correction is estimated to be generated. As described above, the Hamming distance of the component code including the channel-induced error is less than about 1 bit on average, and the Hamming distance of the component code induced by the erroneous correction is about 16 bits on average (in the case of the component code having the parity length of 32 bits). Therefore, the value of the threshold value TH_B may be set as a value that can distinguish between the two of them (for example, 9). The calculation method M2 can be interpreted as a method of not counting the Hamming distance smaller than the threshold TH_B.

When the excess number count that is the evaluation value E1 is larger than the threshold TH_A, the determiner 104 determines that the decoding has failed.

An example of FIG. 9 will be described. It is assumed that the threshold TH_B is 9 and the threshold TH_A is 3. A numerical value in FIG. 9 represents a Hamming distance (contribution value) of each component code. For example, since the component code in the first row includes an error in the parity bit, the contribution value is 1.

During inerrable correction, since there is no component code whose Hamming distance is larger than the threshold TH_B=9, the excess number count becomes 0. Since the value of the excess number count is smaller than the threshold TH_A=3, the determiner 104 determines that the decoding has succeeded.

During erroneous correction, since there is six component codes whose Hamming distance is larger than the threshold TH_B=9, the excess number count becomes 6. Since the value of the excess number count is larger than the threshold TH_A=3, the determiner 104 determines that the decoding has failed.

In the calculation method M2, if the threshold TH_B is appropriately set, the contribution value of the component code including the channel-induced error is not counted. Therefore, even if the component code number increases, the excess number count does not cumulatively increase. Therefore, it is possible to suppress determining as false positive.

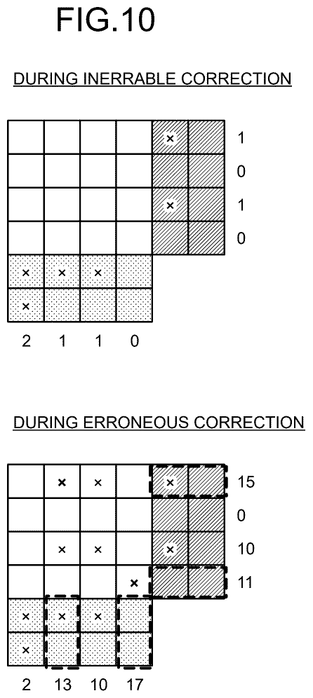

Next, the calculation method M3 will be described. The calculation method M3 is a method of calculating the evaluation value E1 only from the component code having the upper contribution value. FIG. 10 is a diagram for explaining an example of determination processing using the evaluation value E1 calculated by the calculation method M3.

In the calculation method M3, the sum of L Hamming distances (upper L contribution values) is calculated as the evaluation value E1 in descending order of values. Note that an average value may be used instead of the sum.

When the evaluation value E1, which is the sum of the upper L contribution values, is larger than the threshold TH_A, the determiner 104 determines that the decoding has failed.

An example of FIG. 10 will be described. It is assumed that L is 4 and the threshold TH_A is 30. A numerical value in FIG. 10 represents a Hamming distance (contribution value) of each component code.

During inerrable correction, the evaluation value E1, which is the sum of the upper four Hamming distances, is 2+1+1+1=5. Since the value 5 of the evaluation value E1 is smaller than the threshold TH_A=30, the determiner 104 determines that the decoding has succeeded.

During erroneous correction, the evaluation value E1, which is the sum of the upper four Hamming distances, is 17+15+13+11=56. Since the value 56 of the evaluation value E1 is larger than the threshold TH_A=30, the determiner 104 determines that the decoding has failed.

In the calculation method M3, the evaluation value E1 is calculated from contribution values of a limited number (L) of component codes. Therefore, even if the component code number increases, the contribution value of the component code does not accumulate, and as a result, it is possible to suppress determining as false positive.

In the above description, the determination processing is executed both after the decoding processing DEC1 using the outer code succeeds and after the checking processing using the outer code succeeds (in FIG. 4, steps S105 and S110). The determination processing may be executed by only one of these.

### Second Embodiment

In the second embodiment, still another calculation method is used for the evaluation value E1. Hereinafter, an example of a decoder 18-2 according to the second embodiment will be described. Note that the configuration other than the decoder 18-2 is similar to that of the first embodiment.

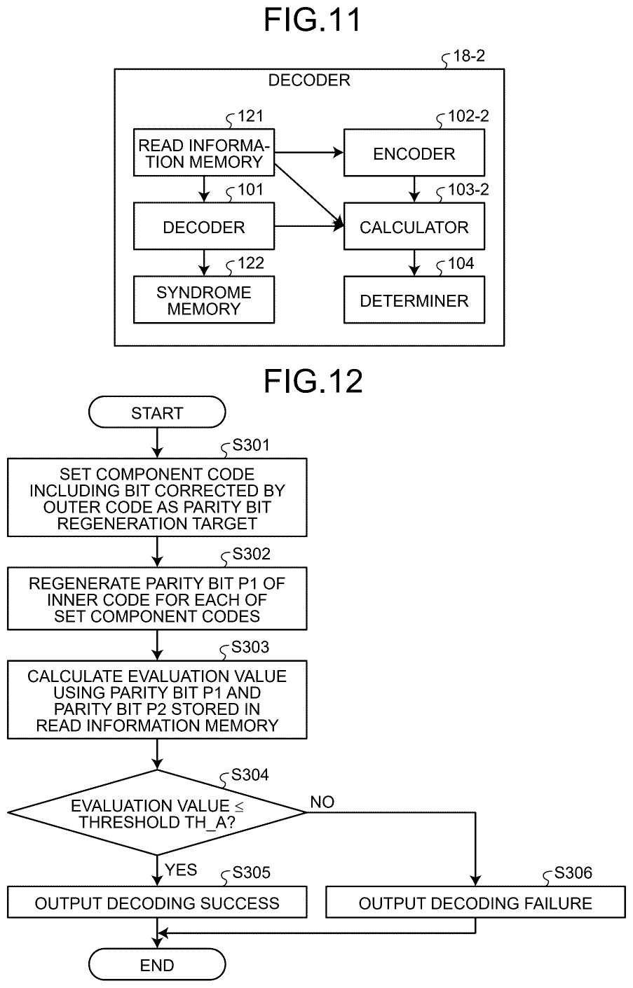

FIG. 11 is a block diagram illustrating a schematic configuration example of the decoder 18-2 of the second embodiment. As illustrated in FIG. 11, the decoder 18-2 includes a read information memory 121, a syndrome memory 122, a decoder 101, an encoder 102-2, a calculator 103-2, and a determiner 104.

In the second embodiment, functions of the encoder 102-2 and the calculator 103-2 are different from those of the first embodiment. Other configurations and functions are similar to those in FIG. 3 that is a block diagram of the decoder 18 according to the first embodiment, and thus, are denoted by the same reference numerals, and description thereof is omitted here.

In the present embodiment, the following calculation method M4 of the evaluation value E1 is used.

(M4) The Hamming distance between the parity bit P1 and the parity bit P2 is calculated for the component code including the bit corrected by the outer code. The statistical value of the Hamming distance is calculated as the evaluation value E1. The statistical value is, for example, a sum or an average value.

Therefore, the encoder 102-2 regenerates the parity bit P1 for the component code including the bit corrected by the outer code. For example, when the decoding processing DEC1 using the outer code is executed, the decoder 18-2 stores information indicating whether or not the component code is a component code including a bit corrected by the outer code in a memory such as the read information memory 121. The encoder 102-2 can specify whether or not the component code is a component code including a bit corrected by an outer code with reference to this information. Hereinafter, a set of component codes including bits corrected with outer codes is referred to as a set S.

The calculator 103-2 calculates the evaluation value E1 using the regenerated parity bit P1 and parity bit P2 for each component code included in the set S. For example, the calculator 103-2 calculates a Hamming distance between the parity bit P1 and the parity bit P2 for each component code included in the set S, and calculates a sum of a plurality of Hamming distances for each component code included in the set S as the evaluation value E1.

Since the calculation method M4 of the present embodiment is assumed to be corrected with the outer code, the calculation method M4 can be applied to determination processing after the decoding processing DEC1 using the outer code is executed. For example, in FIG. 4, the calculation of the evaluation value E1 by the calculation method M4 is applied in the determination processing of step S110. Note that the procedure of other decoding processing is similar to that of the first embodiment (FIG. 4), and thus description thereof is omitted.

Next, the procedure of determination processing of the present embodiment will be described. FIG. 12 is a flowchart illustrating an example of determination processing according to the second embodiment.

The decoder 18-2 sets the component code including the bit corrected by the outer code as the parity bit regeneration target in the decoding processing DEC1 executed in step S108 in FIG. 4, for example (step S301).

The encoder 102-2 regenerates the parity bit P1 of the inner code for each of the set component codes (step S302). The calculator 103-2 calculates the evaluation value E1 using the regenerated parity bit P1 and the parity bit P2 of the inner code for each set component code (step S303).

Since steps S304 to S306 are the same processes as steps S203 to S205 in the determination processing of the first embodiment (FIG. 5), the description thereof will be omitted.

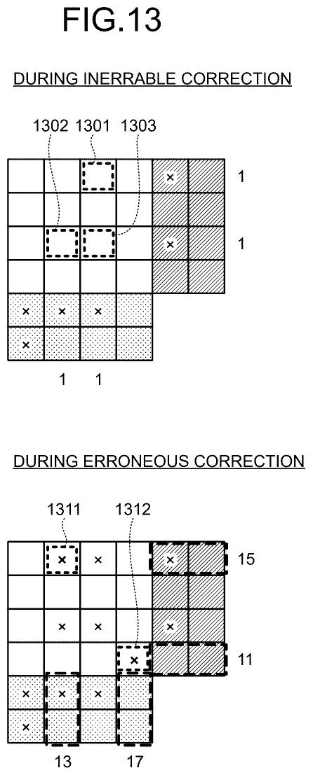

FIG. 13 is a diagram for explaining an example of determination processing using the evaluation value E1 calculated by the calculation method M4. Areas 1301 to 1303 represent areas including bits corrected by the decoding processing DEC1 using the outer code. Areas 1311 and 1312 represent areas to which a new error has been added due to erroneous correction in the decoding processing DEC1.

In the calculation method M4, the component code including the bit corrected by the outer code is included in the set S to be processed. An example of FIG. 13 will be described. It is assumed that the threshold TH_A is 30.

During inerrable correction, four component codes corresponding to the first row, the third row, the second column, and the third column are included in the set S. The evaluation value E1, which is the sum of the Hamming distances of the four component codes included in the set S, is 1+1+1+1=4. Since the value 4 of the evaluation value E1 is smaller than the threshold TH_A=30, the determiner 104 determines that the decoding has succeeded.

During erroneous correction, four component codes corresponding to the first row, the fourth row, the second column, and the fourth column are included in the set S. The evaluation value E1, which is the sum of the Hamming distances of the four component codes included in the set S, is 15+11+13+17=56. Since the value 56 of the evaluation value E1 is larger than the threshold TH_A=30, the determiner 104 determines that the decoding has failed.

In the calculation method M3, the evaluation value E1 is calculated by the contribution value of the component code including the bit corrected with the outer code, in other words, the limited number of component codes. Therefore, even if the component code number increases, the contribution value of the component code does not accumulate, and as a result, it is possible to suppress determining as false positive.

### Third Embodiment

In the embodiments described above, the checking processing is executed by, for example, the following procedure. In a case where the syndrome SD1 of the outer code is satisfied and the syndrome SD2 of the component codes of the inner codes whose number is equal to or larger than the threshold is satisfied, a check result indicating that no error is included in the read information is output.

In such a procedure, for example, when the number of component codes of inner codes in which the syndrome SD2 is not satisfied is large, there is a possibility that it is determined that the read information includes an error even in a case where the read information does not include an error. That is, there is a possibility that a false positive determination (check) is performed in the checking processing.

Therefore, in the third embodiment, an example of checking processing capable of suppressing the determination of a false positive will be described. Hereinafter, an example of a decoder 18-3 according to the third embodiment will be described. Note that the configuration other than the decoder 18-3 is similar to that of the first embodiment.

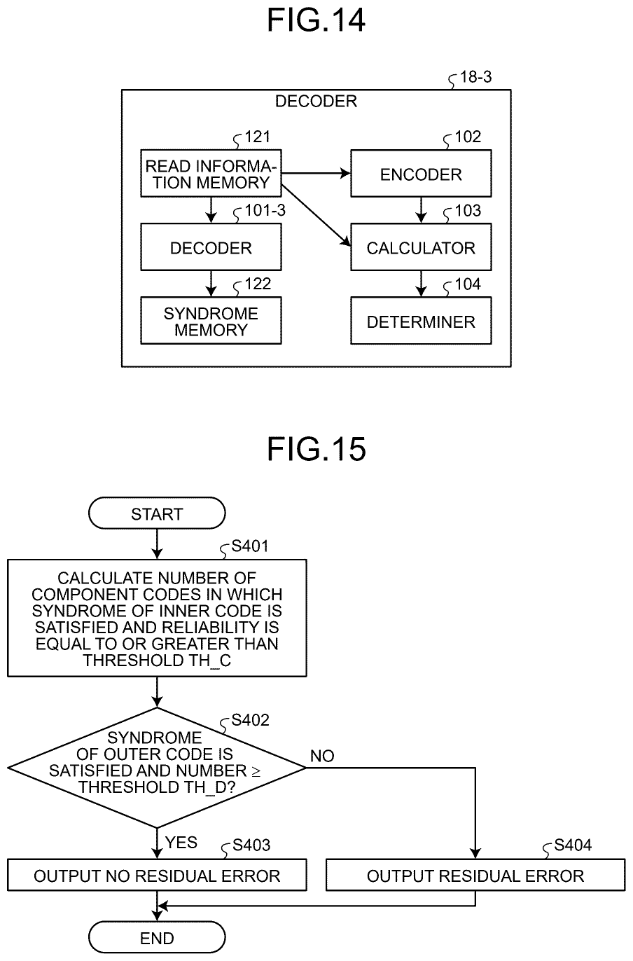

FIG. 14 is a block diagram illustrating a schematic configuration example of the decoder 18-3 of the third embodiment. As illustrated in FIG. 11, the decoder 18-3 includes a read information memory 121, a syndrome memory 122, a decoder 101-3, an encoder 102, a calculator 103, and a determiner 104.

In the third embodiment, a function of a decoder 101-3 is different from that of the first embodiment. Other configurations and functions are similar to those in FIG. 3 that is a block diagram of the decoder 18 according to the first embodiment, and thus, are denoted by the same reference numerals, and description thereof is omitted here.

The decoder 101-3 further has a function of calculating the reliability of correction of each of the plurality of component codes when executing the decoding processing DEC2 using the inner code. The reliability is information indicating certainty of decoding of each component code (decoding reliability).

The reliability is, for example, a metric that is calculated from the soft decision input value and indicates whether the probability that the code word is the original component code word is high or low. Note that the soft decision input value is a received word (probability information) read as information of the probability of being ‘0’ or the probability of being ‘1’ and input to the decoder 18. For example, as the reliability in the binary code, the likelihood calculated from the soft decision input value for the code word can be used. The reliability is not limited thereto, and for example, the following information may be used:
(I1) Probability value for correct code word;
(I2) Value of distance function between code word and soft decision input value; and
(I3) Value obtained by applying a logarithmic function or the like to the value indicated in (I1) or (I2) described above.

The decoder 18-3 executes the checking processing using the outer code and the evaluation value E2 (second evaluation value) based on the calculated reliability. The evaluation value E2 is, for example, the number of component codes in which the syndrome SD2 is satisfied and the reliability is equal to or greater than a threshold TH_C (second threshold). The evaluation value E2 may be, for example, the number of component codes whose reliability is equal to or greater than the threshold TH_C without considering whether the syndrome SD2 is satisfied. The evaluation value E2 may be a sum of reliability.

For example, the decoder 18-3 executes the checking processing by the following procedure. In a case where the syndrome SD1 of the outer code is satisfied and the evaluation value E2 is equal to or larger than a threshold TH_D, a check result indicating that no error is included in the read information is output.

Next, the procedure of checking processing of the present embodiment will be described. The checking processing is applied as a process corresponding to step S103 in FIG. 4, for example. Note that the procedure of other decoding processing is similar to that of the first embodiment (FIG. 4), and thus description thereof is omitted. FIG. 15 is a flowchart illustrating an example of checking processing according to the present embodiment.

The decoder 18-3 calculates, as the evaluation value E2, the number of component codes in which the syndrome SD2 of the inner code is satisfied and the reliability is equal to or greater than the threshold TH_C (step S401). The decoder 18-3 determines whether the syndrome of the outer code is satisfied and the number calculated in step S401 (evaluation value E2) is equal to or larger than the threshold TH_D (step S402).

When the syndrome of the outer code is satisfied and the number is equal to or larger than the threshold TH_D (step S402: Yes), the decoder 18-3 outputs a check result indicating no residual error (step S403), and ends the checking processing.

When the syndrome of the outer code is not satisfied and the number is not equal to or larger than the threshold TH_D (step S402: No), the decoder 18-3 outputs a check result indicating that there is a residual error (step S404), and ends the checking processing.

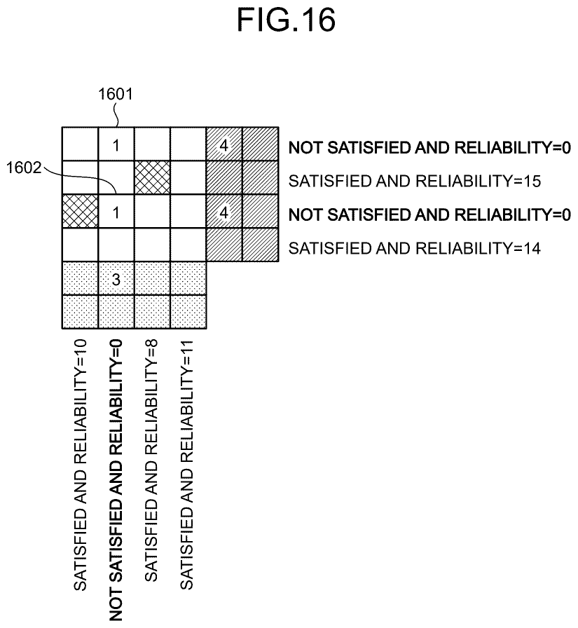

FIG. 16 is a diagram for explaining an example of checking processing according to the present embodiment. Note that the numerical value in the code indicates the number of errors remaining in the corresponding area. It is assumed that the threshold TH_C is 2 and the threshold TH_D is 5.

In the example of FIG. 16, the number of component codes in which the syndrome SD2 of the inner code is satisfied and the reliability is equal to or greater than a threshold TH_C is 5. If the errors in areas 1601 and 1602 are corrected by the decoding processing DEC1 using the outer code, the syndrome SD1 of the outer code is satisfied. Since the syndrome of the outer code is satisfied and the number 5 is equal to or larger than a threshold TH_D=5, the decoder 18-3 outputs the check result indicating no residual error.

In the first and second embodiments, since the checking processing is executed using only the information on whether or not the syndrome of each component code of the inner code is satisfied without considering the reliability, it is necessary to set the threshold for determination strict in order to prevent erroneous correction. For example, it is assumed that if the syndrome of the outer code is satisfied and the number of component codes satisfied by the syndrome is equal to or larger than a threshold TH_E, a check result indicating that there is no residual error is output, and if not, a check result indicating that there is a residual error is output. In such a configuration, it is necessary to set the threshold value TH_E to be large, which may increase the number of times of determination of false positive (that is, it is determined that there is a residual error although there is actually no residual error). In the present embodiment, since the checking processing is executed in consideration of the reliability, it is possible to suppress the determination of false positive by appropriately setting the threshold TH_C to be compared with the reliability.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a non-volatile memory configured to store a concatenated code of a first error-correcting code generated using data to be stored and a second error-correcting code generated using the first error-correcting code; and
a memory controller configured to:
read, from the non-volatile memory, read information;
execute a second decoding processing using the second error-correcting code on the read information;
execute a first decoding processing using the first error-correcting code on the read information when decoding by the second decoding processing fails;
when the first decoding processing or a checking processing of checking that the read information does not include an error by using the first error-correcting code succeeds, generate a first parity bit that is a parity bit of the second error-correcting code, and calculate a first evaluation value for determining whether or not the read information includes the error by using the generated first parity bit and a second parity bit that is a parity bit of the second error-correcting code after the second decoding processing is executed; and
determine whether or not the read information includes the error by using the first evaluation value.

2. The memory system according to claim 1, wherein
the second error-correcting code includes an N-dimensional error-correcting code in which at least one symbol of symbols forming a code is protected by N component code groups, N being an integer of 2 or more,
the second decoding processing includes decoding M (1≤i≤N, where ni is a number of component codes included in the i-th dimensional component code group, and M is a sum of ni) component codes included in the read information, and
the memory controller is configured to:
generate first parity bits for the M component codes when the checking processing determines that no error is included in the read information; and
calculate the first evaluation value by using the generated M first parity bits and second parity bits of the M component codes after the second decoding processing is executed.

3. The memory system according to claim 2, wherein
the memory controller is configured to calculate Hamming distances between the first parity bits and the second parity bits for the M component codes, and calculate the first evaluation value that is a number of component codes, among the M component codes, in which the Hamming distance is equal to or greater than a first threshold.

4. The memory system according to claim 2, wherein
the memory controller is configured to calculate Hamming distances between the first parity bits and the second parity bits for the M component codes, and calculate the first evaluation value that is a sum of a predetermined number of Hamming distances, among the calculated M Hamming distances, in descending order.

5. The memory system according to claim 2, wherein
the memory controller is configured to calculate Hamming distances between the first parity bits and the second parity bits for one or more component codes to be corrected by the first decoding processing among the M component codes, and calculate the first evaluation value that is a statistical value of the calculated Hamming distances.

6. The memory system according to claim 5, wherein
the statistical value of the calculated Hamming distances is a sum or an average value of the calculated Hamming distances.

7. The memory system according to claim 1, wherein the second error-correcting code includes an N-dimensional error-correcting code in which at least one symbol of symbols forming a code is protected by N component code groups, N being an integer of 2 or more,
the second decoding processing includes decoding M (1≤i≤N, where ni is a number of component codes included in the i-th dimensional component code group, and M is a sum of ni) component codes included in the read information, and
the memory controller is configured to execute the checking processing by using the first error-correcting code and a second evaluation value based on reliabilities of correction of the M component codes by the second decoding processing, each of the reliabilities of correction corresponding to each of the M component codes.

8. The memory system according to claim 7, wherein
the second evaluation value includes:
a number of component codes in which a syndrome is satisfied and the reliability is equal to or greater than a second threshold value, among the M component codes;
a number of component codes of which the reliability is equal to or greater than the second threshold value, among the M component codes; or
a sum of the reliabilities.

9. The memory system according to claim 1, wherein
the second error-correcting code includes an N-dimensional error-correcting code in which at least one symbol of symbols forming a code is protected by N component code groups, N being an integer of 2 or more,
the second decoding processing includes decoding M (1≤i≤N, where ni is a number of component codes included in the i-th dimensional component code group, and M is a sum of ni) component codes included in the read information, and
the memory controller is configured to execute the checking processing every time each of the M component codes is decoded.

10. A method of controlling a non-volatile memory configured to store a concatenated code of a first error-correcting code generated using data to be stored and a second error-correcting code generated using the first error-correcting code, the method comprising:
reading, from the non-volatile memory, read information;
executing a second decoding processing using the second error-correcting code on the read information;
executing a first decoding processing using the first error-correcting code on the read information when decoding by the second decoding processing fails;
when the first decoding processing or a checking processing of checking that the read information does not include an error by using the first error-correcting code succeeds, generating a first parity bit that is a parity bit of the second error-correcting code, and calculating a first evaluation value for determining whether or not the read information includes the error by using the generated first parity bit and a second parity bit that is a parity bit of the second error-correcting code after the second decoding processing is executed; and
determining whether or not the read information includes the error by using the first evaluation value.

11. The method according to claim 10, wherein
the second error-correcting code includes an N-dimensional error-correcting code in which at least one symbol of symbols forming a code is protected by N component code groups, N being an integer of 2 or more,
the second decoding processing includes decoding M (1≤i≤N, where ni is a number of component codes included in the i-th dimensional component code group, and M is a sum of ni) component codes included in the read information, and
the method comprises:
generating first parity bits for the M component codes when the checking processing determines that no error is included in the read information; and
calculating the first evaluation value by using the generated M first parity bits and second parity bits of the M component codes after the second decoding processing is executed.

12. The method according to claim 11, further comprising:
calculating Hamming distances between the first parity bits and the second parity bits for the M component codes, and calculating the first evaluation value that is a number of component codes, among the M component codes, in which the Hamming distance is equal to or greater than a first threshold.

13. The method according to claim 11, further comprising:
calculating Hamming distances between the first parity bits and the second parity bits for the M component codes, and calculating the first evaluation value that is a sum of a predetermined number of Hamming distances, among the calculated M Hamming distances, in descending order.

14. The method according to claim 11, further comprising:
calculating Hamming distances between the first parity bits and the second parity bits for one or more component codes to be corrected by the first decoding processing among the M component codes, and calculating the first evaluation value that is a statistical value of the calculated M Hamming distances.

15. The method according to claim 14, wherein
the statistical value of the calculated Hamming distances is a sum or an average value of the calculated Hamming distances.

16. The method according to claim 10, wherein
the second error-correcting code includes an N-dimensional error-correcting code in which at least one symbol of symbols forming a code is protected by N component code groups, N being an integer of 2 or more,
the second decoding processing includes decoding M (1≤i≤N, where ni is a number of component codes included in the i-th dimensional component code group, and M is a sum of ni) component codes included in the read information, and
the method comprises executing the checking processing by using the first error-correcting code and a second evaluation value based on reliabilities of correction of the M component codes by the second decoding processing, each of the reliabilities of correction corresponding to each of the M component codes.

17. The method according to claim 16, wherein
the second evaluation value includes:
a number of component codes in which a syndrome is satisfied and the reliability is equal to or greater than a second threshold value, among the M component codes;
a number of component codes of which the reliability is equal to or greater than a second threshold value, among the M component codes; or
a sum of the reliabilities.

18. The method according to claim 10, wherein the second error-correcting code includes an N-dimensional error-correcting code in which at least one symbol of symbols forming a code is protected by N component code groups, N being an integer of 2 or more,
the second decoding processing includes decoding M (1≤i≤N, where ni is a number of component codes included in the i-th dimensional component code group, and M is a sum of ni) component codes included in the read information, and
the method comprises executing the checking processing every time each of the M component codes is decoded.
